(19) United States
(12) Patent Application Publication
(10) Pub. No.: US 2011/0301891 A1
(43) Pub. Date: Dec. 8, 2011

(54) METHOD OF DIAGNOSING DETERIORATION OF CELL OF BATTERY FOR VEHICLE

(75) Inventor: Woosung Kim, Hwaseong (KR)

(73) Assignees: KIA MOTORS CORPORATION, Seoul (KR); HYUNDAI MOTOR COMPANY, Seoul (KR)

(21) Appl. No.: 12/913,141

(22) Filed: Oct. 27, 2010

(30) Foreign Application Priority Data
Jun. 8, 2010 (KR) 10-2010-0053758

(51) Int. Cl. G01R 31/36

(52) U.S. Cl. 702/63

(57) ABSTRACT

Provided is a method of diagnosing deterioration of a cell of a battery for a vehicle. The present method makes it possible to prevent deterioration of a battery pack and reduction of performance due to degradation. The methods include calculating internal resistance in the method of least squares based on current and voltage of each cell in a battery pack, calculating available capacity and power of the cells from the internal resistance, determining whether the cells are deteriorated on the basis of the available capacity and power, and instructing a driver to check and repair the battery pack if needed.

### CROSS-REFERENCE TO RELATED APPLICATIONS

The present application claims priority to Korean Patent Application Number 10-2010-0053758 filed Jun. 8, 2010, the entire contents of which application is incorporated herein for all purposes by this reference.

### BACKGROUND OF THE INVENTION

1. Field of the Invention

The present invention relates to a method of diagnosing deterioration of a cell of a vehicle battery, and more particularly, to a method of diagnosing deterioration of a cell of a vehicle battery which can calculate internal resistance and determine whether a cell is deteriorated on the basis of the internal resistance, using current and voltage of each cell in a battery pack.

2. Description of Related Art

In general, hybrid vehicles use as a power source a motor operated by electric power applied from a high-voltage battery, in addition to the engine. Electric vehicles use as a power source a motor operated by electric power outputted from a high-voltage battery. With such vehicles, it is possible to reduce exhaust gas and improve fuel efficiency.

Hybrid vehicles and electric vehicles are driven by electric power supplied from a battery pack, which is a high-voltage battery formed by connecting a plurality of rechargeable battery cells in a series. These battery cells are chargeable and dischargeable.

The high-voltage battery may become deteriorated when used for a long time. During use, the battery uses an internal reversible electrochemical reaction to generate electric power, which can result in deterioration. While the deterioration may be similar among a plurality of the same batteries operating under the same conditions, the deterioration among cells of a given battery may differ because all of the cells of the battery generally cannot operate under completely identical conditions.

In addition, the output and capacity of the cells in a given battery pack changes as a result of the difference in deterioration among cells. As a result, the performance of a battery pack system and the vehicle may be decreased.

The information disclosed in this Background of the Invention section is only for enhancement of understanding of the general background of the invention and should not be taken as an acknowledgement or any form of suggestion that this information forms the prior art already known to a person skilled in the art.

### BRIEF SUMMARY OF THE INVENTION

The present invention provides a method of diagnosing deterioration of a cell of a vehicle battery. The present methods can prevent deterioration of a battery pack and reduction of performance due to degradation. In a preferred embodiment, the internal resistance of each cell in the battery pack is calculated from the current and voltage. Based on the internal resistance, it can be determined whether the cells are deteriorated, and the battery pack can be checked and repaired if needed.

An exemplary embodiment of the present invention provides a method of diagnosing deterioration of a cell of a vehicle battery, which includes: measuring current and voltage of the cells of a battery pack and using the measured values to estimate internal resistance of the cells by using the method of least squares; based on the estimated internal resistance, using a stored data table to calculate available capacity and available output; and diagnosing whether one or more of the cells are deteriorated based on the calculated available capacity and available output.

In a preferred embodiment, diagnosing cell deterioration includes: (a) checking cell deterioration based on the calculated available capacity and available output to determine whether the cells are deteriorated; (b) when checking cell deterioration in (a) determines that the cells are not deteriorated, checking internal resistance to determine whether the internal resistance of the cells exceeds two times the average resistance (wherein average resistance is the average of the internal resistance of all the cells); and (c) when the checking cell deterioration in (a) determines that the cells are deteriorated or the checking internal resistance determines in (b) determines that the internal resistance exceeds two times the average resistance, determining that the cells are deteriorated.

In preferred embodiments, the estimated internal resistance is calculated when the temperature of the battery pack is above 25° C. and below 30° C. and the SOC (State Of Charge) of the cells in the battery pack is 50% or more and below 70%.

Another embodiment the present invention provides a method of diagnosing deterioration of a cell of a vehicle battery, which includes: measuring current and voltage of the cells of a battery pack and estimating the internal resistance of the cells by using the method of least squares based on the measured current and voltage; and diagnosing cell deterioration by determining whether the estimated internal resistance of the cells is abnormally larger than the average resistance, (wherein the average resistance is the average of the internal resistance of all the cells).

In a preferred embodiment, diagnosing cell deterioration includes: determining whether there are cells having internal resistance exceeding two times the average resistance; and when the cells are determined to have an internal resistance exceeding two time of the average resistance, determining that the cells are deteriorated.

According to the present invention, a method is provided for diagnosing deterioration of a cell of a vehicle battery which makes it possible to prevent deterioration of a battery pack and to prevent reduction of performance due to degradation. Deterioration of a cell is diagnosed by calculating internal resistance from the current and voltage of each cell in the battery pack, determining whether the cells are deteriorated on the basis of the calculated internal resistance. Based on the diagnosis, a driver can check and repair the battery pack if needed.

The methods and apparatuses of the present invention have other features and advantages which will be apparent from or are set forth in more detail in the accompanying drawings, which are incorporated herein, and the following Detailed Description of the Invention, which together serve to explain certain principles of the present invention.

### BRIEF DESCRIPTION OF THE DRAWINGS

FIG. 1 is a flowchart illustrating a method of diagnosing deterioration of a cell of a battery for a vehicle according to an exemplary embodiment of the present invention.

FIG. 2 is a graph showing current and voltage distribution for estimating internal resistance in the estimating internal resistance step of FIG. 1.

FIG. 3 is a flowchart illustrating a method of diagnosing deterioration of a cell of a battery for a vehicle according to another exemplary embodiment of the present invention.

FIG. 4 is a flowchart illustrating a method of diagnosing deterioration of a cell of a battery for a vehicle according to another exemplary embodiment of the present invention.

### DETAILED DESCRIPTION OF THE INVENTION

Reference will now be made in detail to various embodiments of the present invention(s), examples of which are illustrated in the accompanying drawings and described below. While the invention(s) will be described in conjunction with exemplary embodiments, it will be understood that present description is not intended to limit the invention(s) to those exemplary embodiments. On the contrary, the invention(s) is/are intended to cover not only the exemplary embodiments, but also various alternatives, modifications, equivalents and other embodiments, which may be included within the spirit and scope of the invention as defined by the appended claims.

The present invention provides a method of diagnosing deterioration of a cell of a vehicle battery. The battery can be any battery commonly used in vehicles, including hybrid and electric vehicles. In particularly preferred embodiments, the battery is a high-voltage battery, which is a battery pack composed of a plurality of cells that are usually connected in series. As such, the following methods are suitable for use on all types of vehicle batteries.

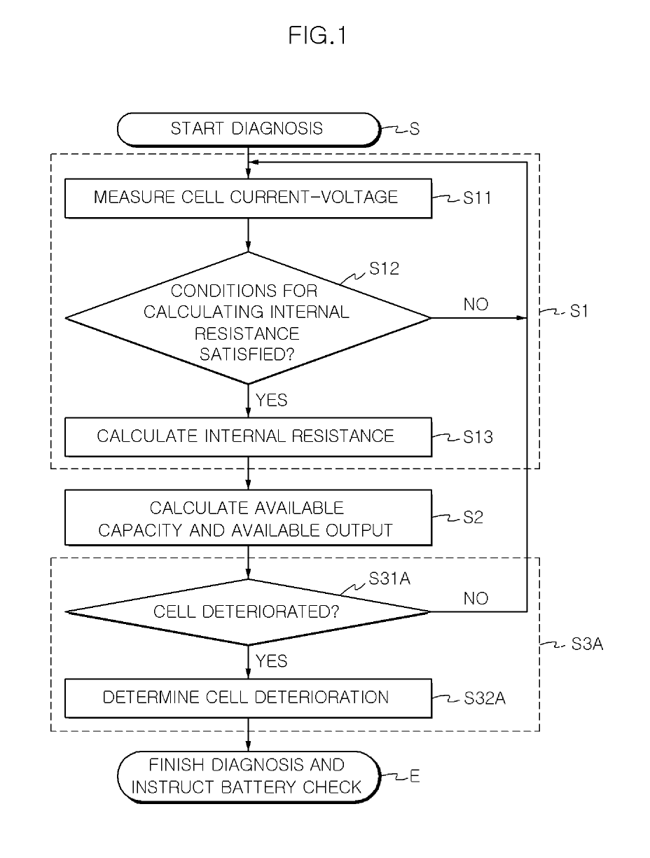

As shown in FIG. 1, a method of diagnosing deterioration of a cell of a battery for a vehicle includes estimating internal resistance (S1), calculating available capacity and available output (S2), and diagnosing cell deterioration (S3A).

In the estimating internal resistance (S1) stage, first the current and voltage of the cells of the high-voltage battery are measured, and then the internal resistance of the cells is estimated by using the method of least squares based on the measured current and voltage.

For example, as shown in FIG. 1, the estimating internal resistance (S1) stage is composed of the step of measuring cell current and voltage (S11) that measures the current and voltage of the cells, the step of checking internal resistance conditions (S12) that checks whether the states of the cells satisfy conditions for calculating the internal resistance, and the step of calculating internal resistance (S13) that calculates the internal resistance of the cells using the method of least squares based on the current and voltage of the cells measured in (S11).

In this configuration, it is possible to measure the current and voltage of the cells using a current sensor and a voltage sensor which are connected to each of the cells. As such, the measurement can be made even when the vehicle is in use. The current sensors and the voltage sensors can further improve reliability in the measured data, by measuring the current and voltage of the cells for one or more seconds in real time at a predetermined period.

In preferred embodiments, the step of checking internal resistance conditions (S12) checks whether the battery is in the range for normal operation, which is preferably above 25° C. and below 30° C., and checks whether the SOC (State Of Charge) of the cells is preferably 50% or more and below 70%. The internal resistance conditions are such that the estimated internal resistance of the cells is not excessively dispersed.

When the temperature and SOC of the battery are satisfied in the step of checking internal resistance conditions (S12), the calculating internal resistance (S13) step is performed to calculate the internal resistance. If the temperature and SOC of the battery are not satisfied in the step of checking internal resistance conditions (S12), the process returns to starting diagnosis (S) and the estimating internal resistance (S1) stage is repeated.

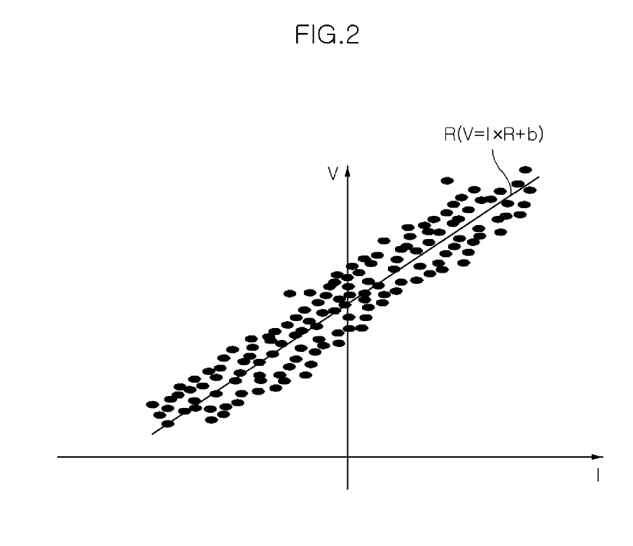

The calculating internal resistance (S13) step shows distribution of the voltage to the current which are measured in the measuring cell current and voltage (S11) step on a coordinate plane, as shown in FIG. 2. In FIG. 2, the inclination R of the line linearly approximating the distribution of current and voltage represents the internal resistance components of the cells. Further, the internal resistance of the cells is approximated and is outputted in a first-order equation, which is a linear equation, by the method of at least squares based on the current I and voltage V.

As shown in FIG. 1, after estimating internal resistance (S1), the method proceeds to the stage of calculating available capacity and available output (S2). The available capacity and the available output to the internal resistance is calculated by the method of least squares, on the basis of a stored data table. The data table is stored in a controller (not shown) and is composed of a table of available capacity to the internal resistance and a table of available power to the internal resistance.

In particular, the data table is composed of a capacity change table storing available capacity changes measured and collected with respect to changes in internal resistance of the cells having the same configuration, and a power change table storing available power changes measured and collected through an experiment with respect to changes in internal resistance. Thus, the data table represents changes in available capacity and available power with respect to the internal resistance.

Therefore, the calculating available capacity and available output (S2) stage calculates the available capacity and the available output of the battery with respect to the internal resistance of the cells, which is calculated in the estimating internal resistance (S1) stage, using the data table stored in the controller.

The method then performs the diagnosing cell deterioration (S3A) stage, which diagnoses whether the cells are deteriorated from the calculated available capacity and available output.

As shown in FIG. 1, the diagnosing cell deterioration (S3A) stage is composed of a step of checking cell deterioration (S31A) that checks whether the available capacity and the available output calculated in the calculating available capacity and available output (S2) stage is smaller than reference capacity and output of the battery, and a step of determining cell deterioration (S32A) that determines that the cells having smaller calculated available capacity and available output than the reference capacity and output are deteriorated.

In this configuration, the reference capacity and output of the battery may be set to any percentage, for example 80%, of the initial capacity and output of the cells that are not used yet. It is then determined that the battery was deteriorated when the available capacity and available output of the cells, which are calculated from the internal resistance of the battery, becomes smaller than the percentage (for example 80%) of the cells at the initial state.

If in the checking cell deterioration (S31A) step it is determined that the cells of which the calculated available capacity and available output are the same as or larger than the reference capacity and output of the battery operate in a normal state, the process then returns to starting diagnosis (S) and the estimating internal resistance (S1) stage is repeated.

In come embodiments, the method further provides a finishing and instructing (E) stage that finishes diagnosis of deterioration of the battery cells, and when it is determined that the battery was deteriorated in the diagnosing cell deterioration (S3A) stage, further informs of the deterioration through a cluster etc., and instructs a battery check.

The method of diagnosing deterioration of a cell of vehicle battery makes it possible to prevent deterioration of a battery pack and reduction of performance due to degradation. Such diagnosis can be accomplished by calculating internal resistance from current and voltage of each cell in the battery pack, determining whether the cells are deteriorated on the basis of the internal resistance, and indicating to a driver to check and repair the battery pack.

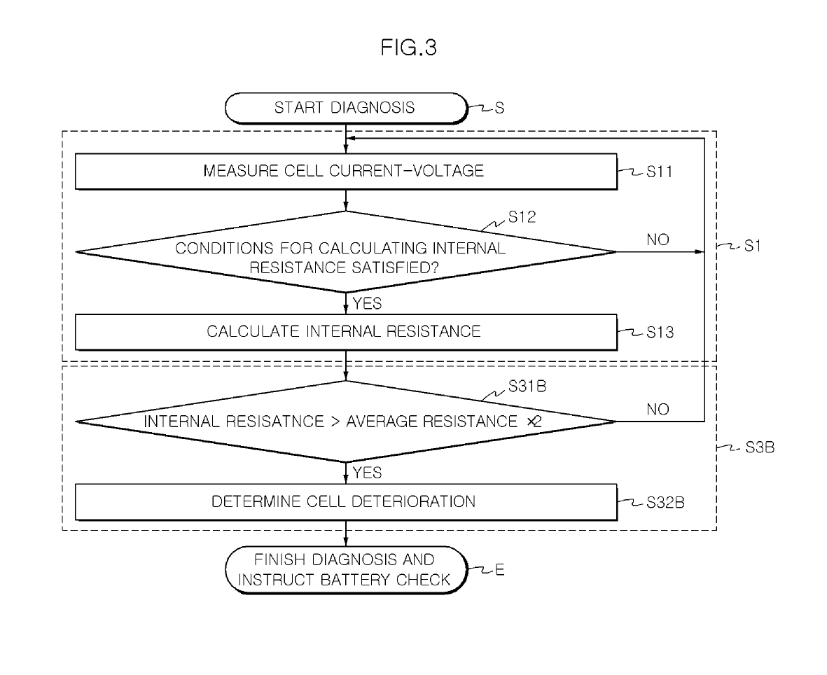

FIG. 3 shows a method of diagnosing deterioration of a cell of a battery for a vehicle in accordance with another embodiment, which includes estimating internal resistance (S1) and diagnosing cell deterioration (S3B). The estimating internal resistance (S1) stage can be similar or the same as the estimating internal resistance (S1) stage described and illustrated in connection with FIG. 1; followed by the diagnosing cell deterioration (S3B) stage as further described below.

in accordance with FIG. 3, the diagnosing cell deterioration (S3B) stage checks whether the internal resistance of the cell which is calculated in the estimating internal resistance (S1) stage is abnormally larger than average resistance, (wherein average resistance is the average of the internal resistance of all the cells). The cells having internal resistance abnormally larger than the average resistance are deteriorated. In other words, whether the cells are deteriorated is based on the internal resistance, because the cells that are relatively rapidly deteriorated among all the cells in the battery pack show internal resistance abnormally larger than the average resistance.

In this embodiment, as shown in FIG. 3, the diagnosing cell deterioration (S3B) stage is composed of a step of checking internal resistance (S31B) that calculates average resistance (wherein average resistance is the average of the internal resistance of all the cells in a battery pack) and compares the internal resistance to a value that is two times the calculated average resistance, and a step of determining cell deterioration (S32B) that determines that the cells having internal resistance greater than two times the average resistance are deteriorated.

As shown in FIG. 3, when it is determines that the cells have internal resistance smaller than two times the average resistance in step (S3B) and thus operate in a normal state, the process returns to starting diagnosis (S) and the estimating internal resistance (S1) starts again.

In some embodiments, when it is determined that the have internal resistance the same as or larger than two times the average resistance in step (S3B), the method can further proceed to and performs a finishing and instructing (E) check that finishes the diagnosis of the cells in the battery, informs whether the cells are deteriorated, and instructs a battery check if needed.

The present method of diagnosing deterioration of a cell of a vehicle battery makes it possible to prevent deterioration of a battery pack and reduction of performance due to degradation. In particular, methods of the invention calculate internal resistance from current and voltage measurements of each cell in the battery pack, determine whether the cells are deteriorated on the basis of the internal resistance, and instructing a driver to check and repair the pack if needed.

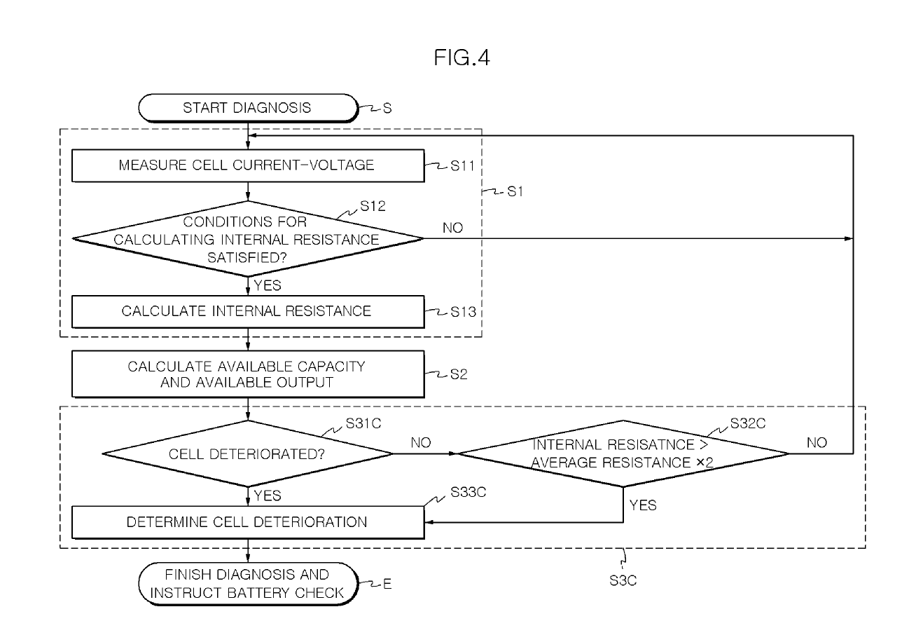

As shown in FIG. 4, a further method of diagnosing deterioration of a cell of a battery for a vehicle includes estimating internal resistance (S1), calculating available capacity and available output (S2), and diagnosing deterioration of a cell (S3C). In some embodiments, the estimating internal resistance (S1) stage and the calculating available capacity and available output (S2) stage can be similar or the same as the estimating internal resistance (S1) stage and the calculating available capacity and available output (S2) stage, which were described and illustrated in connection with FIG. 1; followed by the diagnosing deterioration of a cell (S3C) stage as further described below.

In this embodiment, as shown in FIG. 4, the diagnosing deterioration of a cell (S3C) stage diagnoses whether the cells are deteriorated on the basis of (1) the available capacity and the available output which are calculated in the calculating available capacity and available output (S2) stage, and (2) the internal resistance of the cells which is calculated in the estimating internal resistance (S1) stage.

In a preferred embodiment as shown n FIG. 4, the diagnosing cell deterioration (S3C) stage includes a step of checking cell deterioration (S31C) that checks whether the available capacity and available output (which are calculated in the calculating available capacity and available output (S2) stage) are smaller than the reference capacity and output of the battery, a step of checking internal resistance (S32C) that calculates average resistance (wherein average resistance is the average of the internal resistance of all the cells in the battery pack) and compares a value that is two times the calculated average resistance with the internal resistance of the cells, and a step of determining cell deterioration (S33C) that determines that the cells having calculated available capacity and available output values that are smaller than the reference capacity and output of the battery, and the cells having internal resistance exceeding two times of the average resistance, were deteriorated.

For example, the reference capacity and output of the battery can be set to a percentage, such as 80%, of the initial capacity and output of the cells that are not used yet in the checking cell deterioration (S31C) step. The method performs the step of determining cell deterioration (S33C) that determines the battery was deteriorated when the available capacity and available output of the cells (which are calculated from the internal resistance of the battery) becomes smaller than 80% of the cells at the initial state. In some embodiments, after performing the determining cell deterioration (S33C) step the method further performs a finishing and instructing (E) check that finishes diagnosis of deterioration of the battery cells, informs that there is deterioration through a cluster etc., and instructs a battery check if needed.

If in the step of checking cell deterioration (S31C) it is determined that the cells are not deteriorated, the method proceeds to perform the step of checking internal resistance (S32C) in order to determine again whether the cells of which the available capacity and available output calculated in the checking cell deterioration (S31C) are the same as or larger than the reference capacity and output of the battery were deteriorated, on the basis of the internal resistance.

The determining cell deterioration (S33C) step then determines that the cells having internal resistance the same as or larger than two times of the average resistance in the checking internal resistance (S32C) were deteriorated. The method can then perform a finishing and instructing (E) check that finishes diagnosis of deterioration of the battery cells, informs the deterioration through a cluster etc., and instructs a battery check, after performing the determining cell deterioration (S33C) step.

In accordance with preferred embodiments, if the cells are determined to have internal resistance smaller than two times of the average resistance in the checking internal resistance (S32C) step and thus operate in a normal state, the process returns to starting diagnosis (S) and the estimating internal resistance (S1) step begins again.

The present method of diagnosing deterioration of a cell of a vehicle battery makes it possible to prevent deterioration of a battery pack and reduction of performance due to degradation. In particular, the present method accomplishes this by calculating internal resistance from current and voltage of each cell in the battery pack, determining whether the cells are deteriorated on the basis of the internal resistance, and instructing a driver to check and repair the battery pack if needed.

The foregoing descriptions of specific exemplary embodiments of the present invention have been presented for purposes of illustration and description. They are not intended to be exhaustive or to limit the invention to the precise forms disclosed, and obviously many modifications and variations are possible in light of the above teachings. The exemplary embodiments were chosen and described in order to explain certain principles of the invention and their practical application, to thereby enable others skilled in the art to make and utilize various exemplary embodiments of the present invention, as well as various alternatives and modifications thereof. It is intended that the scope of the invention be defined by the Claims appended hereto and their equivalents.

What is claimed is:

1. A method of diagnosing deterioration of a cell of a battery for a vehicle, the method comprising:
measuring current and voltage of the cells and estimating internal resistance of the cells using the method of least squares based on the measured current and voltage;
using a stored data table to calculate available capacity and available output based on the estimated internal resistance
diagnosing cell deterioration based on the calculated available capacity and available output.

2. The method as defined in claim 1, wherein the diagnosing cell deterioration includes:
(a) diagnosing whether the cells are deteriorated based on the calculated available capacity and available output;
(b) if the cells are diagnosed as not being deteriorated in (a), calculating an average of the internal resistance of all of the cells and determining whether the estimated internal resistance in the cells is greater than two times the average of the internal resistance of all of the cells; and
(c) determining that the cells are deteriorated if the cells are diagnosed as being deteriorated in (a) or if the estimated internal resistance is greater than two times the average of the internal resistance of all of the cells.

3. The method as defined in claim 1, wherein estimating internal resistance calculates the internal resistance when the temperature of the battery pack is between 20° C. and 30° C. above 25° C. and below 30° C. and the state of change of the cells in the battery pack is 50% or more and below 70%.

4. A method of diagnosing deterioration of a cell of a battery for a vehicle, the method comprising:
measuring the current and voltage of the cells and estimating internal resistance of the cells by using the method of least squares based on the measured current and voltage;
calculating an average of the internal resistance of all of the cells; and
determining whether the estimated internal resistance of the cells is abnormally larger than the average of the internal resistance of all the cells;
wherein cells having an estimated internal resistance abnormally larger than the average of the internal resistance of all the cells are diagnosed as deteriorated.

5. The method as defined in claim 4, wherein the diagnosing cell deterioration includes:
determining whether cells have an estimated internal resistance greater than two times the average of the internal resistance of all of the cells; and
determining that the cells are deteriorated if the cells have an estimated internal resistance greater than two times the average of the internal resistance of all of the cells.
